(19) United States
(12) Patent Application Publication
(10) Pub. No.: US 2025/0305133 A1
(43) Pub. Date: Oct. 2, 2025

(54) METHOD, SYSTEM AND APPARATUS FOR N-METAL FILM DEPOSITION

(71) Applicant: ASM IP Holding B.V., Almere (NL)

(72) Inventors: Wei Li, Chandler, AZ (US); Sisi Wang, Phoenix, AZ (US); Mojtaba Samiee, Tempe, AZ (US); Balaji Kannan, Phoenix, AZ (US)

(21) Appl. No.: 19/086,245

(22) Filed: Mar. 21, 2025

Related U.S. Application Data
(60) Provisional application No. 63/570,164, filed on Mar. 26, 2024.

(51) Int. Cl. C23C 16/455; H01L 21/285; H10D 1/00; H10D 1/66

(52) U.S. Cl. CPC C23C 16/45529; C23C 16/45536; H01L 21/28568; H10D 1/045; H10D 1/66

(57) ABSTRACT

Disclosed is a method, system and apparatus for depositing a composite film, comprising providing a substrate in a reaction chamber, depositing a first material layer comprising a first metal nitride according to a first cyclic deposition process, depositing a second material layer comprising aluminum carbide according to a second cyclic deposition process and depositing a third material layer comprising a second metal nitride according to a third cyclic deposition process.

### CROSS-REFERENCE TO RELATED APPLICATIONS

This application is a nonprovisional of, and claims priority to and the benefit of, U.S. Provisional Patent Application No. 63/570,164, filed Mar. 26, 2024 and entitled “METHOD, SYSTEM AND APPARATUS FOR N-METAL FILM DEPOSITION,” which is hereby incorporated by reference herein.

### FIELD OF INVENTION

The present disclosure generally relates to methods, systems and apparatus suitable for forming one or more layers on a surface of a substrate and to structures including the one or more layers. More particularly, the disclosure relates to methods and systems for forming layers that include a work function layer of a metal-oxide-semiconductor capacitor (MOSCAP) and to structures formed using the methods, systems and apparatus.

### BACKGROUND OF THE DISCLOSURE

Semiconductor fabrication processes for forming semiconductor device structures, for example, transistors, memory elements, and integrated circuits, are wide ranging and may include deposition processes, etch processes, thermal annealing processes, lithography processes, and doping processes, amongst others.

Metal-Oxide-Semiconductor Capacitor (MOSCAP) devices have been a cornerstone of modern electronics, playing a crucial role in the operation of a wide range of electronic devices. Conventionally, titanium carbide (TiC) has been used as an n-type work function (nWF) metal in these devices. This choice of material has served well for planar devices and even for more advanced structures such as FinFETs.

However, as the industry continues to push the boundaries of miniaturization, transitioning from planar structures to FinFETs and now to Gate-All-Around (GAA) structures, the dimensions of these structures have reduced significantly. This miniaturization trend has necessitated a corresponding reduction in the thickness of the n-metal film, which now needs to be less than 50 Angstroms (Å) while still maintaining a lower effective work function (eWF).

This requirement presents a significant challenge with the current TiC process. The process of depositing ultra-thin layers of TiC while maintaining a low eWF is complex and difficult to control. Furthermore, the growth rate of TiC is relatively high, which makes it challenging to achieve the desired thinness.

Accordingly, there is a pressing need for a new n-metal material that not only has a lower eWF but also a lower growth rate. Such a material would enable the continued miniaturization of MOSCAP devices while continuing to optimize performance.

### SUMMARY OF THE DISCLOSURE

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

Disclosed is a method, system and apparatus for depositing a composite film, comprising providing a substrate in a reaction chamber, depositing a first material layer comprising a first metal nitride according to a first cyclic deposition process, depositing a second material layer comprising aluminum carbide according to a second cyclic deposition process and depositing a third material layer comprising a second metal nitride according to a third cyclic deposition process. In some examples, the first metal nitride comprises titanium nitride (TiN) or vanadium nitride (VN) or a combination thereof.

In particular examples, the second metal nitride comprises titanium nitride (TiN), vanadium nitride (VN) or molybdenum nitride (MoN), or a combination thereof.

In some examples, wherein the first metal nitride and the second metal nitride are different. In certain examples, the first metal nitride and the second metal nitride are the same.

In some examples, the aluminum carbide comprises 5-65 atomic percent aluminum. In various examples, the aluminum carbide comprises niobium aluminum carbide. In some examples, the aluminum carbide comprises 5 to 50 atomic percent aluminum and 10 to 50 atomic percent niobium. In some examples, the substrate surface comprises a high-k material.

In various examples, the high-k material is hafnium oxide (HfOx).

In some examples, the first cyclic deposition process comprises contacting the substrate with a first vapor phase precursor, contacting the substrate with a second vapor phase precursor, purging the reaction chamber and repeating one or more operations a), b) or c) or any combination thereof in any order until the first material layer of a first predetermined thickness is deposited on the surface of the substrate. In certain examples, the first vapor phase precursor comprises at least one of titanium tetrachloride (TiCl4), titanium tetraiodide (TiI4), titanium tetrabromide (TiBr3), vanadium fluoride (VF3), vanadium chloride (VCl3), vanadium oxychloride (VOCl3), or a combination thereof. In examples, the second vapor phase precursor comprises at least one of ammonia (NH3), hydrazine (N2H4), a hydrazine derivative, an alkyl-hydrazine, tertbutylhydrazine (C4H9N2H3), methylhydrazine (CH3NHNH2), dimethylhydrazine ((CH3)2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof. In examples, the first material layer comprises TiN or VN. In some examples, the first predetermined thickness is in a range of about 1 angstrom to 15 angstrom.

In certain examples, the second cyclic deposition process comprises contacting the substrate with a third vapor phase precursor, contacting the substrate with a co-reactant or a fourth vapor phase precursor, or a combination thereof, purging the reaction chamber and repeating one or more operations d), c) or f) or any combination thereof in any order until the second material layer of a second predetermined thickness is deposited on the surface.

In some examples, the third vapor phase precursor comprises at least one of Tricthylaluminum (TEA), Tris-isobutyl aluminum (TIBA), Dimethylaluminum Hydride (DMAH), Trimethylaluminum (TMA), tritertbutylaluminum (TTBA), Bis(tert-butylamino) aluminum Hydride (BTBAH), Methyltrichloroaluminum (MTCA), Diethylaluminum Chloride (DEAC) or combinations thereof. In various examples, the coreactant comprises hydrogen (H2), hydrogen plasma, or other excited species of hydrogen.

In some examples, the second material layer comprises aluminum carbide. In particular examples, the second predetermined thickness is in a range of 5 to 30 angstrom. In some examples, a percentage of Al is in the range of 5% to 65%. In some examples, the fourth vapor phase precursor comprises a niobium vapor phase reactant comprising niobium pentachloride (NbCl5), niobium pentafluoride (NbF5), niobium pentaiodide (NbI5), niobium pentabromide (NbBr5), or a combination thereof. In certain examples, the second cyclic deposition process comprises contacting the substrate with the third vapor phase precursor and co-reactant to deposit the second material layer comprising aluminum carbide and subsequently contacting the second material layer with the fourth vapor phase precursor. In some examples, the second material layer comprises niobium aluminum carbide. In certain examples, the second predetermined thickness is 5-50 angstroms. In various examples, the ratio of fourth vapor phase precursor to third vapor phase precursor is in the range of 1:2 to 1:10.

In some examples, a precleaning the reaction chamber prior to contacting the substrate with the first vapor phase precursor wherein precleaning comprises exposing the reaction chamber to ammonia. In examples, a percentage of Al is in the range of 10% to 60%.

In some examples, the third cyclic deposition process comprises contacting the substrate with a fifth vapor phase precursor, contacting the substrate with a sixth vapor phase precursor or contacting the substrate with a seventh vapor phase precursor, or a combination thereof, purging the reaction chamber and repeating one or more operations g), h), or i) or any combination thereof in any order until the third material layer of a third predetermined thickness is deposited on the surface of the substrate.

In certain examples, the fifth vapor phase precursor comprises at least one of titanium tetrachloride (TiCl4), titanium tetraiodide (TiI4), titanium tetrabromide (TiBr3), vanadium fluoride (VF3), vanadium chloride (VCl3), vanadium oxychloride (VOCl3), molybdenum tetrachloride (MoCl4), molybdenum pentachloride (MoCl5), molybdenum (V) trichloride oxide (MoOCl3), molybdenum (VI) tetrachloride oxide (MoOCl4), or molybdenum (IV)dichloride dioxide (MoO2Cl2), or a combination thereof. In some examples, the sixth vapor phase precursor comprises at least one of ammonia (NH3), hydrazine (N₂H₄), a hydrazine derivative, an alkyl-hydrazine, tertbutylhydrazine (C4H9N2H3), methylhydrazine (CH3NHNH2), dimethylhydrazine ((CH3) 2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof. In particular examples, the seventh vapor phase precursor is a silicon containing precursor. In some examples, the silicon containing precursor is silane (SiH4), disilane (Si2H6), monomethyl silane (CH3SiH3), or trisilane (H2Si(SiH3)2), or a combination thereof. In certain examples, the third material layer comprises TIN, VN, MON, TiSiN, VSiN or MoSiN. In some examples, the third predetermined thickness is in the range of 5 to 20 angstroms.

In another example the third cyclic deposition process comprises contacting the substrate with the fifth vapor phase precursor and the sixth vapor phase precursor to deposit the third material layer comprising a metal nitride and subsequently contacting the third material layer with the seventh vapor phase precursor.

For purposes of summarizing the invention and the advantages achieved over the prior art, certain objects and advantages of the invention have been described herein above. Of course, it is to be understood that not necessarily all such objects or advantages may be achieved in accordance with any particular example of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these examples are intended to be within the scope of the invention herein disclosed. These and other examples will become readily apparent to those skilled in the art from the following detailed description of certain examples having reference to the attached figures, the invention not being limited to any particular example(s) disclosed.

### BRIEF DESCRIPTION OF THE DRAWING FIGURES

While the specification concludes with claims particularly pointing out and distinctly claiming what are regarded as examples of the invention, the advantages of examples of the disclosure may be more readily ascertained from the description of certain examples of the examples of the disclosure when read in conjunction with the accompanying drawings, in which:

FIG. 1 illustrates a schematic diagram of a reactor system, in accordance with an example of the present technology.

FIG. 2 illustrates a schematic diagram of a reactor system having multiple reaction chambers, in accordance with an example of the present technology.

FIGS. 3A-3B illustrate exemplary structures in accordance with embodiments of the disclosure.

FIG. 4 illustrates an exemplary structure in accordance with embodiments of the disclosure.

FIG. 5 illustrates an exemplary structure in accordance with embodiments of the disclosure.

FIG. 6A illustrates an example process for depositing a composite film, in accordance with examples of the present disclosure.

FIG. 6B illustrates an example cyclic deposition process, in accordance with examples of the present disclosure.

FIG. 6C illustrates an example cyclic deposition process, in accordance with examples of the present disclosure.

FIG. 6D illustrates an example cyclic deposition process, in accordance with examples of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the term “cyclic deposition” may refer to the sequential introduction of one or more precursors and/or reactants into a reaction chamber to deposit a film over a substrate and includes deposition techniques such as atomic layer deposition and cyclic chemical vapor deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

A number of example materials are given throughout the examples of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

The present disclosure includes methods for depositing a low effective work function (eWF) n-metal layer. Such films may be utilized in a number of applications, such as, for example, in semiconductor device applications such as, for example, in MOSCAPs (Metal-Oxide-Semiconductor Capacitors), GAA (Gate-All-Around) devices, and/or CFETs (Complementary Field-Effect Transistors). In MOSCAP devices, the work function of the metal gate is crucial for determining the threshold voltage of the device. A low eWF can help achieve a desired threshold voltage which impacts the device characteristics. Use of low work function metal gate material can provide higher gate controllability. Work function tuning is an important aspect of transistor device control.

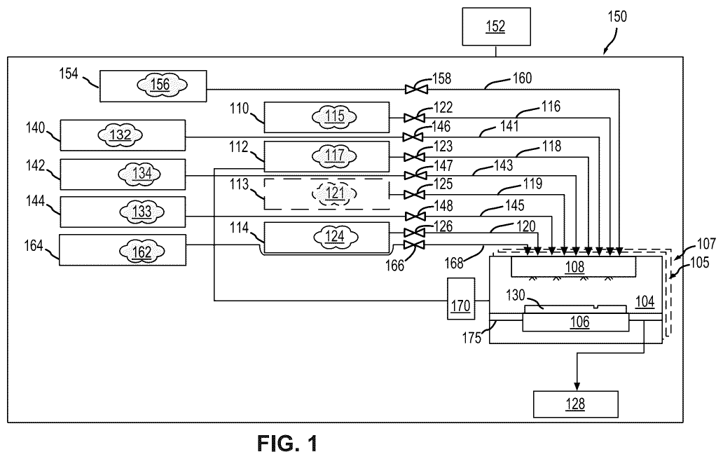

FIG. 1 is a schematic illustration representing an abstraction of an example reactor system 150. Reactor system 150 may comprise one or more reaction chambers 104, 105 and 107, each housing a susceptor 106 to hold a substrate 130 during processing, a fluid distribution system 108 (e.g., a showerhead) to distribute one or more reactants to a surface of substrate 130. Reactor system 150 may include a direct plasma source 175 incorporated within any of chambers 104, 105 or 107 and/or a remote plasma source 170 coupled to any of chambers 104, 105 or 107. Multiple deposition and/or etching processes may be carried out in a single reaction chamber 104 and/or various processes may be carried out in separate reaction chambers 104, 105 and/or 107.

For simplicity, reactant sources and carrier/purge gas sources are shown coupled to a single reaction chamber 104, however, it should be understood that reactant sources and carrier/purge gases for separate processes may be coupled to respective reaction chambers for those specific processes.

In an example, reactant (or co-reactant) sources vessels 110, 112, 113, 114, 140, 142, 144, 164 and/or a carrier or purge gas source vessel 154, may be fluidly coupled to reaction chamber 104 via respective lines 116, 118, 119, 120, 141, 143, 145, 168 and 160, and respective valves or controllers 122, 123, 125, 126, 146, 147, 148, 166 and 158.

In an example, reactant gases may be contained in the above noted vessels and may be applied to substrate 130 in a reaction chamber during processing. For example, first vapor phase precursor 115 may be contained in vessel 110, second vapor phase precursor 117 may be contained in vessel 112, third vapor phase precursor 121 may be contained in vessel 113, fourth vapor phase precursor 124 may be contained in vessel 114, co-reactant 132 may be contained in vessel 140, fifth vapor phase precursor 134 may be contained in vessel 142 (in some examples, first vapor phase precursor 115 and fifth vapor phase precursor 134 may be the same precursor and may be contained in a same vessel (e.g., both first vapor phase precursor 115 and fifth vapor phase precursor 134 may be contained in vessel 110 or vessel 142), sixth vapor phase precursor 133 may be contained in vessel 144 (in some examples, second vapor phase precursor 117 and sixth vapor phase precursor 133 may be the same precursor and may be contained in a same vessel (e.g., both second vapor phase precursor 117 and sixth vapor phase precursor 133 may be contained in vessel 112 or vessel 144), seventh vapor phase precursor 162 may be contained in vessel 164, purge and/or carrier gas may be contained in vessel 156 and/or other materials from respective source vessels can be applied to substrate 130 in reaction chamber 104.

In an example, carrier or purge gas 156 from gas source vessel 154 may be an inert gas and can be flowed to and through the reaction chamber (e.g. reaction chamber 104) to remove any excess reactant or other undesired materials from reaction chamber 104. System 150 can also comprise a vacuum source (e.g., vacuum source 128) fluidly coupled to the reaction chamber, which can be configured to evacuate reactants, a purge gas, or other materials out of the reaction chamber. Carrier or purge gas 156 may comprise argon, helium, neon, krypton, nitrogen and/or xenon, or the like, or combination thereof.

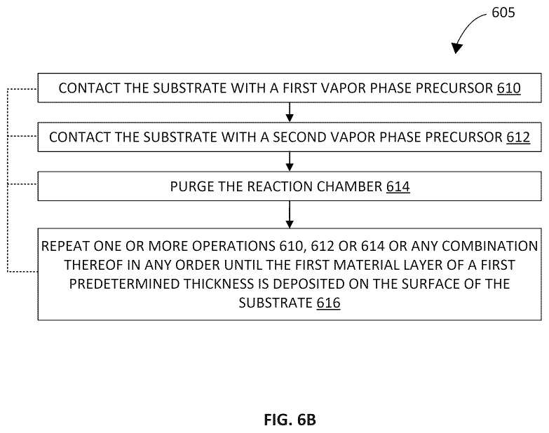

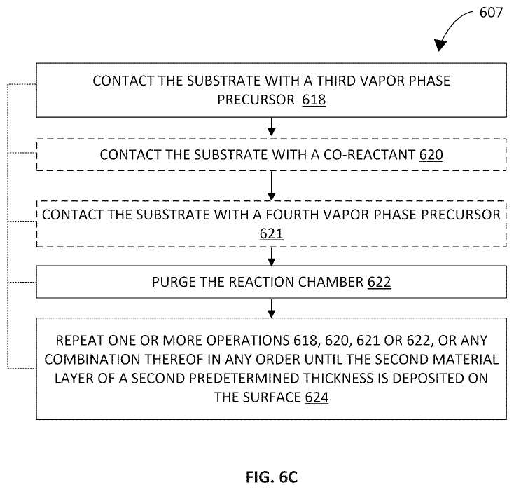

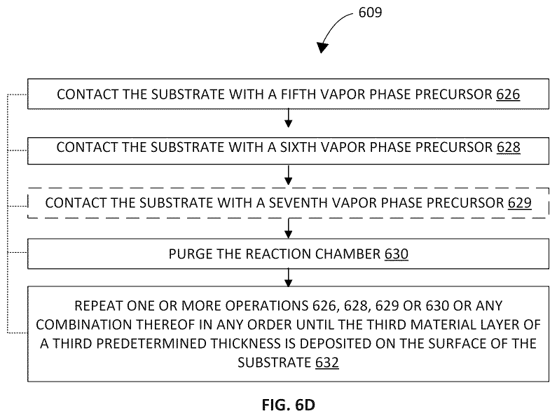

In an example, controller 152 can be configured to perform various functions and/or steps as described herein. Controller 152 can include one or more microprocessors, memory elements, and/or switching elements to perform the various functions. Although illustrated as a single unit, controller 152 can alternatively comprise multiple devices. By way of example, controller 152 can be used to control gas flow (e.g., by monitoring flow rates and controlling valves 122, 123, 125, 126, 146, 147, 148, 158 and/or 166), motors, showerhead 108, remote plasma source 170, heaters, cooling devices and/or vacuum source 158 to execute various processes (e.g., processes 600, 605, 607, and/or 609 shown in respective FIGS. 6A, 6B, 6C, and/or 6D). Further, when a system includes two or more reaction chambers, as described in more detail below, the two or more reaction chambers can be coupled to the same/shared controller.

“Composite film” as used herein refers to a film consisting of different material layers that remain substantially distinct. The layers may serve specific purposes and contribute to the overall properties of the film. Diffusion may occur between adjacent layers, allowing chemicals or substances to move across the interfaces and to become incorporated into adjacent film. Such diffusion may be intentional or unintentional.

In an example, system 150 may perform a thin film deposition or composite film deposition process to deposit one or more material layers on a surface of substrate 130. In an example, a composite film may be formed by a first material layer comprising a first metal nitride deposited on a high-k surface of substrate 130. The composite film may further comprise a second material layer comprising aluminum carbide. In some examples, the second material layer make comprise niobium aluminum carbide. In some examples the composite film may further comprise a third material layer comprising a second metal nitride deposited on the second material layer. In some examples, the first metal nitride may be a titanium nitride, titanium silicon nitride, silicon doped titanium nitride, vanadium nitride, vanadium silicon nitride and/or silicon doped vanadium nitride. In certain non-limiting examples, the second metal nitride may comprise titanium nitride, titanium silicon nitride, silicon doped titanium nitride, vanadium nitride, vanadium silicon nitride, silicon doped vanadium nitride, molybdenum nitride, molybdenum silicon nitride, and/or silicon doped molybdenum nitride. In some examples, the first metal nitride and the second metal nitride may be the same. In other examples, the first metal nitride and the second metal nitride may be different.

In an example, a process for depositing a composite film may comprise a plurality of sub-cycles. In a first sub-cycle, first cyclic deposition process, a first vapor phase precursor 115 and a second vapor phase precursor 117 may contact the substrate 130 depositing a first metal nitride layer on the substrate 130. In a second cyclic deposition process, a third vapor phase precursor 121, a fourth vapor phase precursor 124 and/or a co-reactant 140 may contact the substrate 130 depositing an aluminum carbide layer and/or a niobium aluminum carbide layer on the substrate 130. In a third cyclic deposition process, a fifth vapor phase precursor 134, a sixth vapor phase precursor 133 and optionally a seventh vapor phase precursor 164 may contact the substrate 130 depositing a second metal nitride layer and/or a second metal nitride layer containing silicon on the substrate 130. In an example, the first metal nitride may be deposited according to the third cyclic deposition process.

In the first cyclic deposition process, depositing the first metal nitride layer on substrate 130 may comprise pulsing first vapor phase precursor 115 from reactant source vessel 110 to reaction chamber 104 via showerhead 108. Second vapor phase precursor 117 may be pulsed with or separately from first vapor phase precursor 115 from reactant source vessel 112 to reaction chamber 104 via showerhead 108. As first vapor phase precursor 115 and second vapor phase precursor 117 contact substrate 130 a first metal nitride may form on substrate 130. The reaction chamber 104 may be purged with a purge gas 156 between one or more pulses of first vapor phase precursor 115, second vapor phase precursor 117 and/or between one or more deposition cycles. The first cyclic deposition process (or portions thereof) may be repeated until a desired thickness of the first material layer is reached.

In the second sub-cycle, a second cyclic deposition process for depositing the aluminum carbide layer on substrate 130 may involve pulsing the third vapor phase precursor 121 from reactant source vessel 113 to reaction chamber 104 via showerhead 108. The co-reactant 132 and/or fourth vapor phase precursor 124 may be pulsed either simultaneously or separately with the third vapor phase precursor 121 from their respective reactant source vessels 140 and 114 to reaction chamber 104 via showerhead 108. In an example, the third vapor phase precursor 121 and the co-reactant 132 may contact substrate 130 to form an aluminum carbide layer thereon.

In another example, third vapor phase precursor 121 and fourth vapor phase precursor 124 may come into contact with substrate 130 to form a niobium aluminum carbide layer.

In another example, third vapor phase precursor 121 and co-reactant 132 may contact substrate 130 to form an aluminum carbide layer thereon. Subsequent to formation of the aluminum carbide layer, substrate 130 may be exposed to fourth vapor phase precursor 124 to form a niobium aluminum carbide layer or niobium doped aluminum carbide layer by a soak process. A “soak process” may comprise a deposition process whereby after the initial precursors (e.g., third vapor phase precursor 121 and co-reactant 132) have been pulsed onto the substrate and a layer is formed (e.g., aluminum carbide layer), an additional precursor (e.g., fourth vapor phase precursor 124) may be introduced into the chamber. The additional precursor may react with the newly formed layer (e.g., aluminum carbide layer) at the surface and certain components of the precursor (e.g., niobium) may diffuse into the layer creating a gradient (e.g., a niobium gradient) within the newly formed layer (e.g., the aluminum carbide layer). The additional precursor may be exposed and in contact with the newly formed layer for extended periods of time (e.g., seconds or minutes, depending on the application). Such extended exposure time may be produced by repeated pulses of the additional precursor or by extending the length of one and/or more pulses. The diffused species from the precursor may form a stable layer and enable controlled diffusion of the added species into the existing layer.

In various examples, between one or more pulses of the third vapor phase precursor 121, the co-reactant 132, and/or the fourth vapor phase precursor 124, the reaction chamber 104 can be purged with a purge gas 156. Purging may be performed prior to, during, between and/or after one or more deposition cycles. The second cyclic deposition process (or portions thereof) may be repeated until a desired thickness of the second material layer is reached.

In the third sub-cycle, a third cyclic deposition process for depositing the second metal nitride layer on substrate 130 may comprise pulsing fifth vapor phase precursor 134 from reactant source vessel 142 to reaction chamber 104 via showerhead 108. Sixth vapor phase precursor 133 may be pulsed with or separately from fifth vapor phase precursor 134 from reactant source vessel 144 to reaction chamber 104 via showerhead 108. As fifth vapor phase precursor 134 and sixth vapor phase precursor 133 contact substrate 130, a second metal nitride layer may form on substrate 130.

In another example, subsequent to formation of the second metal nitride layer, substrate 130 may be exposed to seventh vapor phase precursor 162 to form a silicon metal nitride layer or a silicon doped metal nitride layer by a soak process. Seventh vapor phase precursor 162 may be pulsed from reactant source vessel 164 to reaction chamber 104 via showerhead 108. Seventh vapor phase precursor 162 may be pulsed with or separately from fifth vapor phase precursor 134 and/or sixth vapor phase precursor 133. The “soak process” is similar to that described hereinabove and may comprise a deposition process whereby after pulsing the initial precursors (e.g., fifth vapor phase precursor 134 and sixth vapor phase precursor 133) onto the substrate and a layer is formed (e.g., a second metal nitride layer), an additional precursor (e.g., seventh vapor phase precursor 162) may be introduced into the chamber. The additional precursor may react with the newly formed layer (e.g., a second metal nitride layer) at the surface and certain components of the additional precursor (e.g., silicon) may diffuse into the layer creating a silicon gradient within the metal nitride layer. The additional precursor (e.g., seventh vapor phase precursor 162) may be exposed and in contact with the newly formed layer (e.g., a second metal nitride layer) for extended periods of time (e.g., seconds or minutes, depending on the application). Such extended exposure time may be produced by repeated pulses of the additional precursor and/or by extending the length of one or more pulses. The diffused species from the additional precursor may form a stable layer and enable controlled diffusion of the added species into the existing layer.

The reaction chamber 104 may be purged with a purge gas 156 between one or more pulses of fifth vapor phase precursor 134, sixth vapor phase precursor 133 and/or seventh vapor phase precursor 162. Purging may be performed prior to, during, between and/or after one or more deposition cycles. The third cyclic deposition process (or portions thereof) may be repeated until a desired thickness of the third material layer is reached.

In an example, the first material layer, second material layer and/or third material layer may be deposited in the same chamber or may be deposited in different chambers. Moreover, each layer may be deposited separately or in applications other than as in the above-described composite film and claimed subject matter is not limited in this regard. For example, the above-described layers may be useful in device applications other than for work function materials such as in a MOSCAP.

The first material layer, second material layer and/or third material layer may be formed by any of a variety of methods including various deposition cycles.

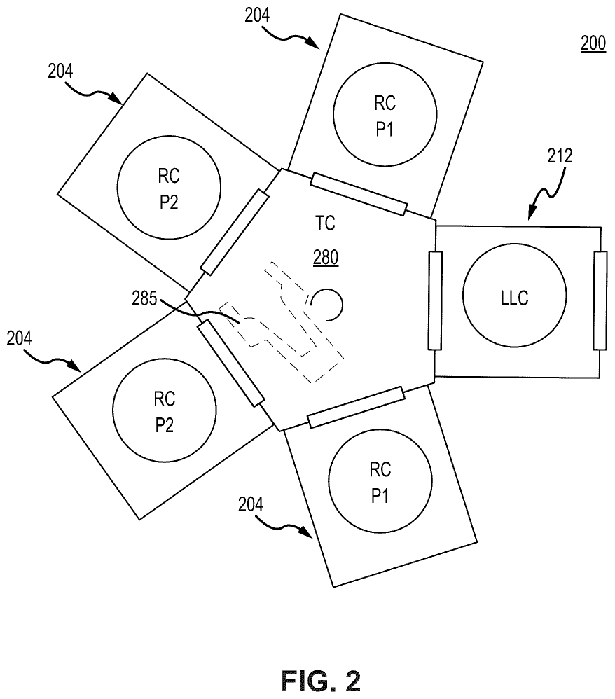

In some examples, a reactor system (e.g., reactor system 150) can comprise multiple reaction chambers. For example, in reactor system 200, shown in FIG. 2, a number of reaction chambers 204 (each of which can be an example of any of reaction chambers 104, 105, and/or 107 in FIG. 1) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 130 can be disposed in different chambers for different steps of a semiconductor manufacturing process (i.e., the first deposition cycle, the second deposition cycle, and/or the third deposition cycle may each be performed in the same or different chambers).

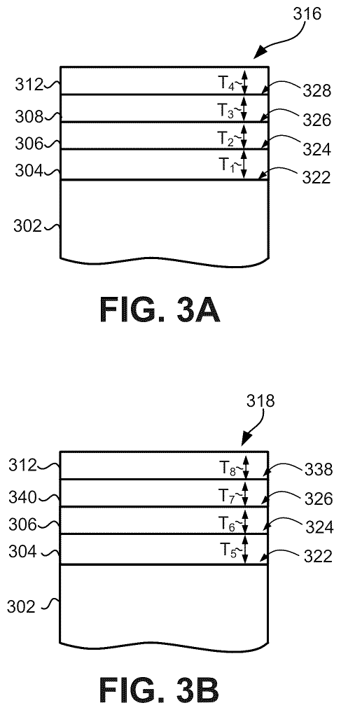

FIG. 3A illustrates a device 316 in accordance with examples of the disclosure. Device 316 may comprise MOSCAP and/or a device incorporated into other specific device architectures, such as a gate stack, planar semiconductor device, FinFET, nanosheet, nanowire, gate-all-around (GAA), complementary FETs (CFETs), and/or any of a variety of other devices and claimed subject matter is not limited in this regard.

In an example, device 316 includes a substrate 302, dielectric or insulating material 304, a liner layer 306, a metal carbide layer 308 and a capping layer 312.

In an example, substrate 302 can be or include any of the substrate materials described hereinabove.

In an example, dielectric or insulating material 304 may be disposed on substrate 302 surface 322 and may be a high-k material, for example, a metallic oxide having a dielectric constant greater than about 7. In some embodiments, the high-k material has a dielectric constant higher than the dielectric constant of silicon oxide. Exemplary high-k materials include one or more of hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and mixtures/laminates comprising one or more such layers. In an example, the thickness T₁ may be less than 100 angstrom (Å), or about 75 Å to about 100 Å, or about 50 Å to about 75 Å, or about 25 Å to about 50 Å, or about 15 Å to about 30 Å, or any appropriate thickness (“about” in this context means +/−10 Å).

In an example, liner layer 306 may be deposited on the dielectric or insulating material 304 surface 324 and may comprise a metal nitride, a metal silicon nitride or a silicon doped metal nitride as discussed in greater detail with respect to FIGS. 6A-6D. In an example, the thickness T₂ may be less than 25 angstrom (Å), or about 1 Å to about 25 Å, 1 Å to about 15 Å, or about 2 Å to about 25 Å, or about 2 Å to about 15 Å, or about 2 Å to about 10 Å, or any appropriate thickness (“about” in this context means plus or minus 2 Å).

In an example, metal carbide layer 308 may comprise a work function layer disposed on liner layer 306 surface 326. Metal carbide layer 308 may be deposited in a cyclic deposition process described in more detail below with respect to FIGS. 6A-6D. In some examples, the metal carbide layer 308 may comprise aluminum carbide. Because metal carbide layer 308 is formed using a cyclical deposition process, a concentration of aluminum, carbon, and/or other constituents in metal carbide layer 308 may be controlled by, for example, controlling the temperature, pressure, and/or pulse times during one or more deposition cycles. In some cases, metal carbide layer 308 can have a stoichiometric composition. In some examples, metal carbide layer 308 can have a non-stoichiometric composition. A work function and other properties of metal carbide layer 308 can be altered by altering an amount of metal, carbon, and/or other constituents in the layer or in a deposition cycle.

In an example, metal carbide layer 308 can include impurities, such as hydrogen and/or oxygen or the like in an amount of less than ten atomic percent, five atomic percent, less than one atomic percent, less than 0.2 atomic percent, less than 0.1 atomic percent, or less than 0.05 atomic percent, alone or combined.

A thickness of metal carbide layer 308 can vary according to application. By way of example, a desired or predetermined thickness of metal carbide layer 308, shown as thickness T₃, may be about 1 Å to about 50 Å, or about 5 Å to about 50 Å, or about 2 Å to about 40 Å, or about 3 Å to about 35 Å, or about 5 Å to about 30 Å, or about 5 Å to about 25 Å, or any appropriate thickness (“about” in this context means plus or minus 5 Å).

A thickness and/or composition of metal carbide layer 308 can be adjusted to obtain a desired work function. In an example, a work function of metal carbide layer 308 may be <4.0 eV, <4.1 eV, <4.2 eV, <4.3 eV, <4.4 eV, <4.5 eV, <4.6 eV, <4.7 eV, or any appropriate work function (“about” in this context means plus or minus 0.1 eV).

In an example, metal carbide layer 308 can be adjusted to obtain a desired percentage of aluminum by adjusting the process window (e.g., temperature, pressure, and/or pulse times and number of pulses). In an example, metal carbide layer 308 may comprise about 65 atomic percent aluminum, or less than about 60 atomic percent aluminum, or less than about 50 atomic percent aluminum, or less than about 40 atomic percent aluminum, or less than about 30 atomic percent aluminum, or less than about 25 atomic percent aluminum, or less than about 20 atomic percent aluminum, or less than about 15 atomic percent aluminum, or less than about 10 atomic percent aluminum, or less than about 5 atomic percent aluminum, or any appropriate atomic percent aluminum (“about” in this context means plus or minus 5%).

In an example, capping layer 312 may be disposed on top surface 328 of aluminum carbide layer 308 and may comprise a metal nitride, a metal silicon nitride or a silicon doped metal nitride as discussed in greater detail with respect to FIGS. 6A-6D. In some examples of capping layer 312 comprising silicon, the silicon may be deposited such that a silicon gradient forms with a greatest concentration of silicon proximate the top portion 342 of capping layer 312. In an example, capping layer 312 may be adjusted to a predetermined thickness, T₄. The predetermined thickness, T₄, may be less than about 100 angstrom (Å), or about 1 Å to about 100 Å, or about 2 Å to about 80 Å, or about 3 Å to about 60 Å, or about 4 Å to about 40 Å, or about 5 Å to about 30 Å, or any appropriate thickness (“about” in this context means plus or minus 5 Å).

FIG. 3B illustrates a device 318 in accordance with examples of the disclosure. Device 318 may comprise MOSCAP and/or a device incorporated into other specific device architectures, such as a gate stack, planar semiconductor device, FinFET, nanosheet, nanowire, gate-all-around (GAA), complementary FETs (CFETs), and/or any of a variety of other devices and claimed subject matter is not limited in this regard.

In an example, device 318 includes a substrate 302, dielectric or insulating material 304, a liner layer 306, a metal carbide layer 340 and a capping layer 312.

In an example, substrate 302 can be or include any of the substrate materials described hereinabove.

In an example, dielectric or insulating material 304 may be disposed on substrate 302 surface 332 and may be a high-k material, for example, a metallic oxide having a dielectric constant greater than about 7. In some embodiments, the high-k material has a dielectric constant higher than the dielectric constant of silicon oxide. Exemplary high-k materials include one or more of hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and mixtures/laminates comprising one or more such layers. In an example, the thickness T₅ may be less than 100 angstrom (Å), or about 75 Å to about 100 Å, or about 50 Å to about 75 Å, or about 25 Å to about 50 Å, or about 1 Å to about 30 Å, or any appropriate thickness (“about” in this context means plus or minus 10 Å).

In an example, liner layer 306 may be deposited on the dielectric or insulating material 304 surface 334 and may comprise a metal nitride, a metal silicon nitride or a silicon doped metal nitride as discussed in greater detail with respect to FIGS. 6A-6D. In an example, the thickness T₆ may be less than 25 angstrom (Å), or about 1 Å to about 25 Å, 1 Å to about 15 Å, or about 2 Å to about 25 Å, or about 2 Å to about 15 Å, or about 2 Å to about 10 Å, or any appropriate thickness (“about” in this context means plus or minus 2 Å).

In an example, metal carbide layer 340 may comprise a work function layer disposed on liner layer 306 surface 326. Metal carbide layer 340 may be deposited in a cyclic deposition process described in more detail below with respect to FIGS. 6A-6D. In some examples, the metal carbide layer 340 may comprise niobium aluminum carbide or niobium doped aluminum carbide. Metal carbide layer 340 can be adjusted to obtain a desired percentage of aluminum by adjusting the process window (e.g., temperature, pressure, and/or pulse times and number of pulses). Additionally, because metal carbide layer 340 is formed using a cyclical deposition process, a concentration of aluminum, carbon, and/or other constituents (e.g., niobium) may be tuned by, for example, controlling the ratio of aluminum-containing precursor to other precursors (e.g., niobium containing precursors) used during deposition.

In an example, controlling the ratio of precursors may be carried out by adjusting pulse cycles and/or the ratio of pulses. For example, in the example where the metal carbide layer 340 comprises niobium aluminum carbide to increase aluminum content in metal carbide layer 340, a ratio of niobium-containing precursor pulses to aluminum-containing precursor pulses may be about 1:1 to 1:10, or about 1:1 to 1:8, or about 1:1 to 1:6, or about 1:1 to 1:4, or about 1:2 to 1:10, or about 1:2 to 1:8, or about 1:2 to 1:6, or about 1:2 to 1:4, or any appropriate pulse ratio (“about” in this context means +/−1 pulse).

Because each layer may be deposited separately or in applications other than as in the above-described composite film, it may be desirable to increase niobium content of metal carbide layer 340 comprising niobium aluminum carbide and to reduce aluminum content. In such an example, a ratio of niobium-containing precursor pulses to aluminum-containing precursor pulses may be about 1:1 to 10:1, or about 1:1 to 8:1, or about 1:1 to 6:1, or about 1:1 to 4:1, or about 2:1 to 10:1, or about 2:1 to 8:1, or about 2:1 to 6:1, or about 2:1 to 4:1, or any appropriate pulse ratio (“about” in this context means +/−1 pulse).

In some cases, metal carbide layer 340 can have a stoichiometric composition. In some examples, metal carbide layer 340 can have a non-stoichiometric composition. A work function and other properties of metal carbide layer 340 can be altered by altering an amount of metal, carbon, and/or other constituents in the layer or in a deposition cycle.

In an example, metal carbide layer 340 can include impurities, such as halides, hydrogen, and/or oxygen or the like in an amount of less than ten atomic percent, five atomic percent, less than one atomic percent, less than 0.2 atomic percent, less than 0.1 atomic percent, or less than 0.05 atomic percent, alone or combined.

A thickness of metal carbide layer 340 can vary according to application. By way of example, a desired or predetermined thickness of metal carbide layer 340, shown as thickness T₇, may be about 1 Å to about 50 Å, or about 5 Å to about 50 Å, or about 2 Å to about 40 Å, or about 3 Å to about 35 Å, or about 5 Å to about 30 Å, or about 5 Å to about 25 Å, or any appropriate thickness (“about” in this context means plus or minus 5 Å).

A thickness and/or composition of metal carbide layer 340 can be adjusted to obtain a desired work function and/or threshold voltage. In an example, a work function of metal carbide layer 308 may be <4.0 eV, <4.1 eV, <4.2 eV, <4.3 eV, <4.4 eV, <4.5 eV, <4.6 eV, <4.7 eV, or any appropriate work function (“about” in this context means plus or minus 0.1 eV).

In an example, metal carbide layer 340 can be adjusted to obtain a desired percentage of aluminum as described herein. In an example, metal carbide layer 340 may comprise about 65 atomic percent aluminum, or less than about 60 atomic percent aluminum, or less than about 50 atomic percent aluminum, or less than about 40 atomic percent aluminum, or less than about 30 atomic percent aluminum, or less than about 25 atomic percent aluminum, or less than about 20 atomic percent aluminum, or less than about 15 atomic percent aluminum, or less than about 10 atomic percent aluminum, or less than about 5 atomic percent aluminum, or any appropriate atomic percent aluminum (“about” in this context means plus or minus 5%).

In an example, capping layer 312 may be disposed on top surface 338 of aluminum carbide layer 340 and may comprise a metal nitride, a metal silicon nitride or a silicon doped metal nitride as discussed in greater detail with respect to FIGS. 6A-6D. In an example, capping layer 312 may be adjusted to a predetermined thickness, T₈. The predetermined thickness, T₈, may be less than about 100 angstrom (Å), or about 1 Å to about 100 Å, or about 2 Å to about 80 Å, or about 3 Å to about 60 Å, or about 4 Å to about 40 Å, or about 5 Å to about 30 Å, or any appropriate thickness (“about” in this context means plus or minus 5 Å).

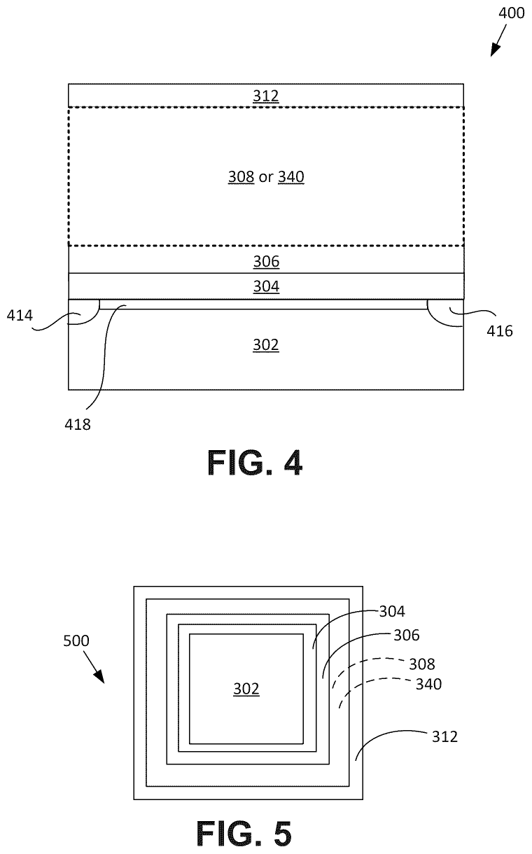

FIG. 4 illustrates another exemplary structure 400, with reference to FIG. 3A and FIG. 3B, in accordance with examples of the disclosure. Device or structure 400 includes a substrate 302, dielectric or insulating material 304, work function layer comprising either aluminum carbide layer 308 or metal carbide layer 340 (as indicated with a dashed line). In the illustrated example, structure 400 also includes liner layer 306 and capping layer 312.

In the illustrated example, substrate 302 includes a source region 414, a drain region 416, and a channel region 418. Although illustrated as a horizontal structure, structures and devices in accordance with examples of the disclosure can include vertical and/or three-dimensional structures and devices, such as FinFET devices.

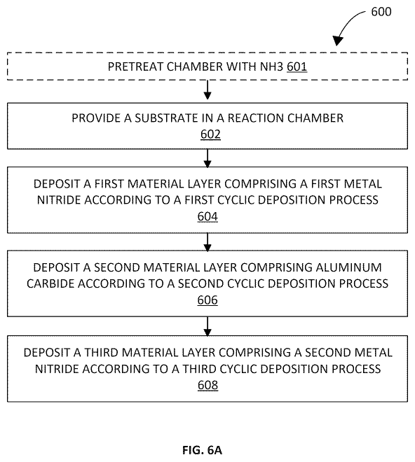

FIG. 5 illustrates another structure 500, with reference to FIG. 3A and FIG. 3B, in accordance with examples of the disclosure. Structure 500 is suitable for gate-all-around field effect transistors (GAA FET) (also referred to as lateral nanowire FET) devices and the like.

In the illustrated example, structure 500 includes substrate 302, dielectric material 304, work function layer comprising either aluminum carbide layer 308 or metal carbide layer 340 (as indicated with dashed lines). In the illustrated example, structure 500 also includes liner layer 306 and capping layer 312.

FIG. 6A illustrates an example process 600 for depositing a composite film. Although the example process 600 depicts a particular sequence of operations, the sequence may be altered without departing from the scope of the present disclosure.

According to some examples, process 600 may begin with optional (as indicated with dashed lines) operation 601 where prior to initiating a deposition process, the reaction chamber (e.g., reaction chamber 104) is pretreated with NH3. Without being limited by theory, it is believed that the ammonia may act to nitridize interior surfaces of the chamber, such as the showerhead (i.e., distribution system 108) to promote aluminum metal formation, leading to formation of aluminum carbide due to decomposition of the aluminum containing precursor. Such nitridization may smooth interior surfaces promoting more efficient use of precursors. Such NH₃ pretreatment may proceed by flowing NH₃ for a predetermined amount of time. For example, NH3 may be flowed into the reaction chamber for between about 1 to 100 seconds, or between about 2 to 90 seconds, or between about 4 to 80 seconds, or between about 5 to 60 seconds, or between about 6 to 50 seconds, or between about 8 to 40 seconds, or between about 9 to 30 seconds, or between about 10 to 20 seconds, or any appropriate amount of time (“about” in this context means +/−5 seconds). NH3 may be flowed into the reaction chamber at a rate of between about .1 to 10.5 slm, or between about 1 to 9 slm, or between about 1.5 to 6.5 slm, or between about 2 to 5 slm, or between about 2 to 4 slm, or any appropriate rate (“about” in this context means +/−2 slm). The pressure of the reaction chamber 104 during pretreatment operation 601 may be between about 0.1 and 100 Torr, or between about .1 and 50 Torr, or between about. 1 and 25 Torr, or between about .1 and 15 Torr, or between about .2 and 10 Torr, or between about .5 and 8 Torr, or between about .5 Torr and 6 Torr, or any appropriate pressure (“about” in this context means +/−5 Torr).

In an example, process 600 may proceed to operation 602 where a substrate is provided in a reaction chamber. The substrate surface may comprise a high-k material. In some embodiments the high-k material may comprise hafnium oxide (HfOx).

In an example, process 600 may proceed to a first cyclic deposition process 605 (see FIG. 6B) at operation 604 where a first material layer (e.g., see FIG. 3A, liner layer 306) comprising a first metal nitride may be deposited. In an example, the first metal nitride may comprise a variety of metal nitrides such as titanium nitride (TiN), molybdenum nitride (MON), or vanadium nitride (VN) or a combination thereof. In some embodiments, the first metal nitride may further comprise silicon such that the first material layer may comprise any of a variety of compounds including titanium silicon nitride, molybdenum silicon nitride, or vanadium silicon nitride or a combination thereof. In an example, the first material layer may comprise a liner layer.

In an example, first cyclic deposition process 605 may be repeated until the first material layer reaches a predetermined thickness.

Process 600 may proceed to a second cyclic deposition process 607 (see FIG. 6C) at operation 606, where a second material layer (e.g., see FIG. 3A, aluminum carbide layer 308 or see FIG. 3B aluminum carbide layer 340) comprising aluminum carbide may be deposited. The second material layer may comprise a percentage of aluminum in the range of about 10%-60%, or about 10%-40%, or about 10%-30%, aluminum. In some embodiments, the second material layer make comprise niobium aluminum carbide. The second material layer may comprise a percentage of niobium in the range of about 10%-50% niobium.

In an example, second cyclic deposition process 607 may be repeated until the second material layer reaches a predetermined thickness.

In an example, process 600 may proceed to a third cyclic deposition process 609 (see FIG. 6D) at operation 608 where a third material layer (e.g., see FIG. 3A, capping layer 312) comprising a second metal nitride may be deposited. In an example, the second metal nitride may comprise a variety of metal nitrides such as titanium nitride (TiN), molybdenum nitride (MoN), or vanadium nitride (VN) or a combination thereof. In some embodiments, the second metal nitride may further comprise silicon such that the third material layer may comprise any of a variety of compounds including titanium silicon nitride, silicon doped titanium nitride, molybdenum silicon nitride, silicon doped molybdenum nitride, vanadium silicon nitride, oe silicon doped vanadium nitride, or a combination thereof. The first metal nitride and the second metal nitride may comprise the same materials or different materials. For example the first metal nitride may not comprise silicon whereas the second metal nitride may comprise silicon. In an example, the second metal nitride may comprise a capping layer.

In an example, third cyclic deposition process 609 may be repeated until the third material layer reaches a predetermined thickness.

In an example, first cyclic deposition process 605, second cyclic deposition process 607 and/or third cyclic deposition process 609 may be conducted in the same reaction chamber (e.g., see FIG. 1, reaction chamber 104). In another example, first cyclic deposition process 605 may be conducted in a first reaction chamber (e.g., see FIG. 1, reaction chamber 104), second cyclic deposition process 607 may be conducted in a second different reaction chamber (e.g., see FIG. 1, reaction chamber 105) and third cyclic deposition process 609 may be conducted in a third different reaction chamber (e.g., see FIG. 1, reaction chamber 107). In another embodiment, any two of first cyclic deposition process 605, second cyclic deposition process 607 and/or third cyclic deposition process 609 may be conducted in the same reaction chamber and a third cyclic deposition process of first cyclic deposition process 605, second cyclic deposition process 607 and/or third cyclic deposition process 609 may be conducted in a different reaction chamber.

FIG. 6B illustrates the first cyclic deposition process 605 of operation 604 (see FIG. 6A) for depositing the first material layer in more detail. Although example process 604 depicts a particular sequence of operations, the sequence may be altered without departing from the scope of the present disclosure. The operations can be executed in a multitude of sequences and repetitions to accommodate specific requirements. In some embodiments, one or more operations may be executed in any order or even omitted entirely, contingent upon the requirements of the process.

In an example, first metal nitride layer may comprise any of a variety of metal nitrides including without limitation, titanium nitride, vanadium nitride, silicon doped titanium nitride, silicon doped vanadium nitride, titanium silicon nitride or vanadium silicon nitride, or a combination thereof.

According to some examples, the process 605 may begin at operation 610 where a first vapor phase precursor (e.g., first vapor phase precursor 115, see FIG. 1) may contact the substrate. In an example the first vapor phase precursor may be a metal-containing precursor and may comprise titanium tetrachloride (TiCl₄), titanium tetraiodide (TiI₄), titanium tetrabromide (TiBr3), vanadium fluoride (VF3), vanadium chloride (VCl3), vanadium oxychloride (VOCl3), or a combination thereof.

According to some examples, process 605 may proceed to operation 612 including contacting the substrate with a second vapor phase precursor (e.g., second vapor phase precursor 117, see FIG. 1) wherein the second vapor phase precursor contains nitrogen. In an example, the second vapor phase precursor may comprise ammonia (NH₃), hydrazine (N₂H₄), a hydrazine derivative, an alkyl-hydrazine, tertbutylhydrazine (C4H9N2H3), methylhydrazine (CH₃NHNH₂), dimethylhydrazine ((CH₃)2N₂H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof.

According to some examples, process 605 includes purging the reaction chamber at operation 614 (e.g., by pulsing a purge gas 156 into the chamber 104, see FIG. 1), as indicated by dashed lines. Purging operation 614 may be executed at any juncture in first cyclic deposition process 605 (e.g., before, after and/or between operations 610, 612, and/or before or after second cyclic deposition process 605). Excess chemical and reaction byproduct, if any, may be removed from reaction chamber by purging. Purging gas (e.g., purge gas 156, see FIG. 1), is preferably any inert as, such as, without limitation, argon (Ar), nitrogen, (N2), or helium (He).

According to some examples, at operation 616, process 605 includes repeating one or more operations 610, 612 or 614 or any combination thereof in any order until the first material layer of a first predetermined thickness is deposited on the surface of the substrate. In an example, the first predetermined thickness of the first material layer is in a range of about 5 angstroms to 15 angstroms.

In some examples, during processing, the temperature of the reaction chamber (e.g., chamber 104) during first cyclic deposition process 605 for depositing a second metal nitride layer may be less than about 600° C., or less than about 550° C., or less than about 500° C., or less than about 450° C., or less than about 400° C., or less than about 300° C. or between about 300° C.-550° C., or any appropriate temperature. The pressure of the reaction chamber during first cyclic deposition process 605 may be between 0.1 and 100 Torr, or between. 1 and 50 Torr, or between .1 and 25 Torr, or between .5 and 8 Torr, 1 torr to 5 Torr, or any appropriate pressure.

In some examples of the disclosure, contacting the substrate with the first vapor phase precursor and/or the second vapor phase may comprise contacting the substrate with the first vapor phase precursor and/or the second vapor phase precursor for a time period of between about 0.01 seconds and about 1000 seconds, or between about 0.05 seconds and about 500 seconds, or between about 0.1 seconds and about 250 seconds, between about 0.01 seconds about 100 seconds, or between about 0.1 seconds and about 50 seconds, or between about 0.1 seconds and about 25 seconds, between about 0.1 seconds about 15 seconds, or between about 0.1 seconds and about 10 seconds, or between about 0.1 seconds and about 5 seconds, or even between 0.2 seconds and 2 second, or any appropriate time period.

FIG. 6C illustrates second cyclic deposition process 607 of operation 606 (see FIG. 6A) for depositing the aluminum carbide layer in more detail. Although example process 607 depicts a particular sequence of operations, the sequence may be altered without departing from the scope of the present disclosure. The operations can be executed in a multitude of sequences and repetitions to accommodate specific requirements. In some embodiments, one or more operations may be executed in any order or even omitted entirely, contingent upon the requirements of the process.

According to some examples, process 607 may begin at operation 618 where the substrate may be contacted with a third vapor phase precursor (e.g., third vapor phase precursor 121, see FIG. 1). In an example, the third vapor phase precursor may comprise at least one of triethylaluminum (TEA), tris-isobutyl aluminum (TIBA), dimethylaluminum hydride (DMAH), trimethylaluminum (TMA), tritertbutylaluminum (TTBA), bis(tert-butylamino)aluminum hydride (BTBAH), methyltrichloroaluminum (MTCA), diethylaluminum chloride (DEAC), AlCl3 or a combination thereof.

In some examples, second material layer may comprise aluminum carbide. In such an example, process 607 may proceed to optional (indicated with dashed lines) operation 620 where the substrate may be contacted with a co-reactant (e.g., co-reactant 132, see FIG. 1). The aluminum carbide layer may be deposited using an aluminum containing precursor that also contains carbon. In such an example, the aluminum component and carbon component maybe both derive from the same precursor. In an example, the co-reactant may be used and may comprise hydrogen (H₂), hydrogen plasma, and/or excited species of hydrogen. Without being limited by theory, it is believed that the hydrogen may act as a reducing agent to promote Al metal formation leading to formation of aluminum carbide due to decomposition of the aluminum containing precursor.

In some embodiments, the second material layer make comprise niobium, for example second material layer may comprise niobium aluminum carbide. Process 607 may comprise contacting the substrate with the third vapor phase precursor at operation 618 and a fourth vapor phase precursor (e.g., fourth vapor phase precursor 124, see FIG. 1) at optional operation 621. Fourth vapor phase precursor may be a niobium containing vapor phase precursor. In certain examples, fourth vapor phase precursor may comprise niobium pentachloride (NbCl5), niobium pentafluoride (NbF5), niobium pentaiodide (NbI5), niobium pentabromide (NbBr5), or a combination thereof. In an example, co-reactant (e.g., H₂) may or may not be used with the third vapor phase precursor and/or fourth vapor phase precursor to produce the second material layer comprising niobium aluminum carbide.

In another example, the second cyclic deposition process 607 may include contacting the substrate with co-reactant (e.g., H2) at optional operation 620 to deposit aluminum carbide and subsequently contacting the aluminum carbide layer with the fourth vapor phase precursor at optional operation 621. In some examples, the contacting the aluminum carbide layer with the fourth vapor phase precursor may be done for a prolonged period of time or over a number of repeated pulses of the fourth vapor phase precursor in a soak process as previously described. In an example, the fourth vapor phase precursor may react with the newly formed layer of aluminum carbide at the surface and niobium may then diffuse into the aluminum carbide layer creating a niobium gradient within the top surface of the aluminum carbide layer where the greatest concentration of niobium may be proximate to the surface of the aluminum carbide layer. The diffused species from the precursor may form a stable layer and enable controlled diffusion of the added species into the existing layer. In an example, the aluminum concentration in the second material layer can be modulated 1) by varying the thickness of the aluminum carbide layer prior to contacting with the fourth vapor phase precursor, wherein a thinner aluminum carbide layer has less aluminum compared to a thicker aluminum carbide layer and 2) exposing to the aluminum carbide layer to the fourth vapor phase precursor for either multiple pulses of selected duration or fewer pulses for longer period of time. Additionally, the aluminum in the second material layer may be removed by AlCl₃ generated during pulsing with a niobium-containing fourth vapor phase precursor. Therefore, the aluminum concentration is tunable by varying the pulse number and duration of a niobium-containing fourth vapor phase precursor.

In an example, second cyclic deposition process 607 may proceed to a reaction chamber purging step at operation 622 (e.g., by pulsing a purge gas into the chamber), as indicated by dashed lines. Purging operation 622 may be executed at any juncture in second cyclic deposition process 607 (e.g., before, after and/or between operations 618, 620, and/or before or after second cyclic deposition process 607). Excess chemical and reaction byproduct, if any, may be removed from reaction chamber by purging. Purging gas is preferably any inert as, such as, without limitation, argon (Ar), nitrogen, (N2), or helium (He).

According to some examples, process 607 may proceed to operation 624 that includes repeating one or more operations 618, 620 or 622 or any combination thereof in any order until the second material layer of a second predetermined thickness is deposited on the surface of the substrate.

In an example, the second predetermined thickness of the second material layer is in a range of about 5 angstrom (Å) to 50 Å.

In some examples, during processing, the temperature of the reaction chamber (e.g., chamber 104) during second cyclic deposition process 607 for depositing a second metal nitride layer may be less than about 600° C., or less than about 550° C., or less than about 500° C., or less than about 450° C., or less than about 400° C., or less than about 300° C. or between about 300° C.-550° C., or any appropriate temperature. The pressure of the reaction chamber during second cyclic deposition process 607 may be between 0.1 and 100 Torr, or between .1 and 50 Torr, or between .1 and 25 Torr, or between .5 and 8 Torr, 1 torr to 5 Torr, or any appropriate pressure.

In some examples of the disclosure, contacting the substrate with the third vapor phase precursor, the fourth vapor phase precursor and/or the co-reactant may comprise contacting the substrate with third vapor phase precursor, the fourth vapor phase precursor and/or the co-reactant for a time period of between about 0.01 seconds and about 1000 seconds, or between about 0.05 seconds and about 500 seconds, or between about 0.1 seconds and about 250 seconds, between about 0.01 seconds about 100 seconds, or between about 0.1 seconds and about 50 seconds, or between about 0.1 seconds and about 25 seconds, between about 0.1 seconds about 15 seconds, or between about 0.1 seconds and about 10 seconds, or between about 0.1 seconds and about 5 seconds, or even between 0.2 seconds and 2 second, or any appropriate time period.

FIG. 6D illustrates an example third cyclic deposition process 609 for depositing a second metal nitride layer. Although the example process 609 depicts a particular sequence of operations, the sequence may be altered without departing from the scope of the present disclosure. The operations can be executed in a multitude of sequences and repetitions to accommodate specific requirements. In some embodiments, one or more operations may be executed in any order or even omitted entirely, contingent upon the requirements of the process.

In an example, second metal nitride layer may comprise any of a variety of metal nitrides including without limitation, titanium nitride, vanadium nitride, molybdenum nitride, silicon doped titanium nitride, silicon doped vanadium nitride, silicon doped molybdenum nitride, titanium silicon nitride, vanadium silicon nitride, and/or molybdenum silicon nitride, or a combination thereof.

According to some examples, process 609 may begin at operation 626 including contacting the substrate with a fifth vapor phase precursor (e.g., see FIG. 1, fifth vapor phase precursor 134). In an example, fifth vapor phase precursor may be a metal containing precursor and may comprise without limitation titanium tetrachloride (TiCl4), titanium tetraiodide (TiI4), titanium tetrabromide (TiBr3), vanadium fluoride (VF3), vanadium chloride (VCl3), vanadium oxychloride (VOCl3), molybdenum tetrachloride (MoCl4), molybdenum pentachloride (MoCl5), molybdenum (V) trichloride oxide (MoOCl3), molybdenum (VI) tetrachloride oxide (MoOCl4), or molybdenum (IV) dichloride dioxide (MoO2Cl2), or a combination thereof.

According to some examples, process 609 may move to operation 628 including contacting the substrate with a sixth vapor phase precursor. In an example, the sixth vapor phase precursor may comprise a nitrogen containing precursor (e.g., see FIG. 1, sixth vapor phase precursor 133). Such nitrogen containing precursors may include without limitation, ammonia (NH3), hydrazine (N2H4), a hydrazine derivative, an alkyl-hydrazine, tertbutylhydrazine (C4H9N2H3), methylhydrazine (CH3NHNH2), dimethylhydrazine ((CH3) 2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof.

In an example, the third cyclic deposition process 609 may proceed to an optional (as indicated by a dashed line) operation 629. Operation 629 may include contacting the substrate with a seventh vapor phase precursor (e.g., see FIG. 1, seventh vapor phase precursor 162). In an example, seventh vapor phase precursor may be a silicon containing precursor.

At operation 629, in some examples, upon completion of one or more of operations 626 and 628, a metal nitride layer may be disposed on the substrate. The metal nitride may be exposed to the seventh vapor phase precursor containing silicon so as to deposit silicon into the metal nitride layer. Operation 629 may include soaking the second metal nitride layer with the seventh vapor phase precursor for a prolonged period of time and/or multiple pulses (e.g., about 1-1000 pulses, or any appropriate number of pulses wherein the pulses have a duration of about 1-10 seconds, or any appropriate pulse duration) in a soak process as previously described. In an example, the seventh vapor phase precursor may interact with the newly formed second metal nitride layer at the surface permitting silicon to diffuse into the metal nitride layer creating a silicon gradient. Thus, the third material layer may comprise a second metal nitride layer comprising a silicon gradient wherein the greatest concentration of silicon may be proximate to a top surface of the second metal nitride layer. The diffused silicon species from the precursor may form a stable layer and enable controlled diffusion of the added species into the existing layer.

The seventh precursor may comprise any appropriate silicon containing precursor such as but not limited to silane (SiH₄), disilane (Si₂H₆), silicon tetrachloride (SiCl₄), hexachlorodisilane (Si₂Cl₆), dichlorosilane (SiH₂Cl₂), monomethyl silane (CH₃SiH₃), and/or trisilane (H₂Si(SiH₃)₂).

In an example, third cyclic deposition process 609 may proceed to a reaction chamber purging step at operation 630 (e.g., by pulsing a purge gas into the chamber), as indicated by dashed lines. Purging operation 630 may be executed at any juncture in third cyclic deposition process 609 (e.g., before, after and/or between operations 626, 628, 629, and/or before or after third cyclic deposition process 609). Excess chemical and reaction byproduct, if any, may be removed from reaction chamber by purging. Purging gas is preferably any inert as, such as, without limitation, argon (Ar), nitrogen, (N2), or helium (He).

According to some examples, process 609 includes repeating one or more operations 626, 628, 629 or 630 or any combination thereof in any order until the third material layer of a third predetermined thickness is deposited on the surface of the substrate at operation 632.

In some examples, process 609 may be applied mutatis mutandis to deposit the first material layer comprising a metal nitride.

In an example, the third predetermined thickness of the first material layer may be in a range of about 5 angstrom (Å) to 30 Å.

In some examples, during processing, the temperature of the reaction chamber (e.g., chamber 104) during third cyclic deposition process 609 for depositing a second metal nitride layer may be less than about 600° C., or less than about 550° C., or less than about 500° C., or less than about 450° C., or less than about 400° C., or less than about 300° C. or between about 300° C.-550° C., or any appropriate temperature. The pressure of the reaction chamber during third cyclic deposition process 609 may be between 0.1 and 100 Torr, or between .1 and 50 Torr, or between .1 and 25 Torr, or between .5 and 8 Torr, 1 torr to 5 Torr, or any appropriate pressure.

In some examples of the disclosure, contacting the substrate with the fifth vapor phase precursor, the sixth vapor phase precursor and/or the seventh vapor phase precursor may comprise contacting the substrate with fifth vapor phase precursor, the sixth vapor phase precursor and/or the seventh sixth vapor phase for a time period of between about 0.01 seconds and about 1000 seconds, or between about 0.05 seconds and about 500 seconds, or between about 0.1 seconds and about 250 seconds, between about 0.01 seconds about 100 seconds, or between about 0.1 seconds and about 50 seconds, or between about 0.1 seconds and about 25 seconds, between about 0.1 seconds about 15 seconds, or between about 0.1 seconds and about 10 seconds, or between about 0.1 seconds and about 5 seconds, or even between 0.2 seconds and 2 second, or any appropriate time period.

It should be appreciated that any conceivable sequence of the deposition, etching processes, purge cycles, and repetitions thereof, is assumed as part of the present disclosure including combinations of deposition, etching processes, purge cycles, and repetitions thereof disclosed with respect to different FIGS. and claimed subject matter is not limited in this regard.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for depositing a composite film, comprising:
providing a substrate in a reaction chamber;
depositing a first material layer comprising a first metal nitride according to a first cyclic deposition process;
depositing a second material layer comprising aluminum carbide according to a second cyclic deposition process; and
depositing a third material layer comprising a second metal nitride according to a third cyclic deposition process.

2. The method of claim 1, wherein the first metal nitride comprises titanium nitride (TiN) or vanadium nitride (VN) or a combination thereof.

3. The method of claim 1, wherein the second metal nitride comprises titanium nitride (TiN), vanadium nitride (VN) or molybdenum nitride (MoN), or a combination thereof.

4. The method of claim 1, wherein the first metal nitride and the second metal nitride are different.

5. The method of claim 1, wherein the first metal nitride and the second metal nitride are the same.

6. The method of claim 1, wherein the aluminum carbide comprises 5-65 atomic percent aluminum.

7. The method of claim 1, wherein the aluminum carbide comprises niobium aluminum carbide.

8. The method of claim 7, wherein the aluminum carbide comprises 5 to 50 atomic percent aluminum and 10 to 50 atomic percent niobium.

9. The method of claim 1, wherein the substrate surface comprises a high-k material.

10. The method of claim 9, wherein the high-k material is hafnium oxide (HfOx).

11. The method of claim 1, wherein the first cyclic deposition process comprises:
a) contacting the substrate with a first vapor phase precursor;
b) contacting the substrate with a second vapor phase precursor;
c) purging the reaction chamber; and
repeating one or more operations a), b) or c) or any combination thereof in any order until the first material layer of a first predetermined thickness is deposited on the surface of the substrate.

12. The method of claim 11, wherein the first vapor phase precursor comprises at least one of titanium tetrachloride (TiCl₄), titanium tetraiodide (TiI₄), titanium tetrabromide (TiBr3), vanadium fluoride (VF3), vanadium chloride (VCl3), vanadium oxychloride (VOCl3), or a combination thereof.

13. The method of claim 12, wherein the second vapor phase precursor comprises at least one of ammonia (NH₃), hydrazine (N2H4), a hydrazine derivative, an alkyl-hydrazine, tertbutylhydrazine (C₄H₉N₂H₃), methylhydrazine (CH₃NHNH₂), dimethylhydrazine ((CH₃)₂N₂H₂), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof.

14. The method of claim 11 wherein the first material layer comprises TiN or VN.

15. The method of claim 14, wherein the first predetermined thickness is in a range of about 1 angstrom to 15 angstrom.

16. The method of claim 1, wherein the second cyclic deposition process comprises:
d) contacting the substrate with a third vapor phase precursor;
e) contacting the substrate with a co-reactant or a fourth vapor phase precursor, or a combination thereof:
f) purging the reaction chamber; and
repeating one or more operations d), e) or f) or any combination thereof in any order until the second material layer of a second predetermined thickness is deposited on the surface.

17. The method of claim 16, wherein the third vapor phase precursor comprises at least one of Triethylaluminum (TEA), Tris-isobutyl aluminum (TIBA), Dimethylaluminum Hydride (DMAH), Trimethylaluminum (TMA), tritertbutylaluminum (TTBA), Bis(tert-butylamino) aluminum Hydride (BTBAH), Methyltrichloroaluminum (MTCA), Diethylaluminum Chloride (DEAC) or combinations thereof.

18. The method of claim 17, wherein the coreactant comprises hydrogen (H₂), hydrogen plasma, or other excited species of hydrogen.

19. The method of claim 18, wherein the second material layer comprises aluminum carbide.

20. The method of claim 19, wherein the second predetermined thickness is in a range of 5 to 30 angstrom.

21. The method of claim 19, wherein a percentage of Al is in the range of 5% to 65%.

22. The method of claim 16, wherein the fourth vapor phase precursor comprises a niobium vapor phase reactant comprising niobium pentachloride (NbCl5), niobium pentafluoride (NbF5), niobium pentaiodide (NbI5), niobium pentabromide (NbBr5), or a combination thereof.

23. The method of claim 22, wherein the second cyclic deposition process comprises contacting the substrate with the third vapor phase precursor and co-reactant to deposit the second material layer comprising aluminum carbide and subsequently contacting the second material layer with the fourth vapor phase precursor.

24. The method of claim 22, wherein the second material layer comprises niobium aluminum carbide.

25. The method of claim 24, wherein the second predetermined thickness is 5-50 angstroms.

26. The method of claim 24, wherein the ratio of fourth vapor phase precursor to third vapor phase precursor is in the range of 1:2 to 1:10.

27. The method of claim 1, further comprising a preleaning the reaction chamber prior to contacting the substrate with the first vapor phase precursor.

28. The method of claim 27, wherein precleaning comprises exposing the reaction chamber to ammonia.

29. The method of claim 26 wherein a percentage of Al is in the range of 10% to 60%.

30. The method of claim 1, wherein the third cyclic deposition process comprises:
g) contacting the substrate with a fifth vapor phase precursor;
h) contacting the substrate with a sixth vapor phase precursor or contacting the substrate with a seventh vapor phase precursor, or a combination thereof;
i) purging the reaction chamber; and
repeating one or more operations g), h), or i) or any combination thereof in any order until the third material layer of a third predetermined thickness is deposited on the surface of the substrate.

31. The method of claim 30, wherein the fifth vapor phase precursor comprises at least one of titanium tetrachloride (TiCl₄), titanium tetraiodide (TiI₄), titanium tetrabromide (TiBr3), vanadium fluoride (VF3), vanadium chloride (VCl3), vanadium oxychloride (VOCl3), molybdenum tetrachloride (MoCl₄), molybdenum pentachloride (MoCl₅), molybdenum (V) trichloride oxide (MoOCl₃), molybdenum (VI) tetrachloride oxide (MoOCl₄), or molybdenum (IV) dichloride dioxide (MoO₂Cl₂), or a combination thereof.

32. The method of claim 31, wherein the sixth vapor phase precursor comprises at least one of ammonia (NH₃), hydrazine (N₂H₄), a hydrazine derivative, an alkyl-hydrazine, tertbutylhydrazine (C₄H₉N₂H₃), methylhydrazine (CH₃NHNH₂), dimethylhydrazine ((CH₃)₂N₂H₂), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof.

33. The method of claim 32, wherein the seventh vapor phase precursor is a silicon containing precursor.

34. The method of claim 33, wherein the silicon containing precursor is silane (SiH₄), disilane (Si₂H₆), monomethyl silane (CH₃SiH₃), or trisilane (H₂Si(SiH₃)₂), or a combination thereof.

35. The method of claim 30, wherein the third material layer comprises TiN, VN, MON, TiSiN, VSIN or MoSiN.

36. The method of claim 30, wherein the third predetermined thickness is in the range of 5 to 20 angstroms.

37. The method of claim 30, wherein the third cyclic deposition process comprises contacting the substrate with the fifth vapor phase precursor and the sixth vapor phase precursor to deposit the third material layer comprising a metal nitride and subsequently contacting the third material layer with the seventh vapor phase precursor.
